(19) United States
(12) Patent Application Publication
(10) Pub. No.: US 2013/0201624 A1
(43) Pub. Date: Aug. 8, 2013

(54) HEAT DISSIPATING SYSTEM

(71) Applicant: GUO-HE HUANG, Shenzhen City (CN)

(72) Inventor: GUO-HE HUANG, Shenzhen City (CN)

(21) Appl. No.: 13/667,245

(22) Filed: Nov. 2, 2012

(30) Foreign Application Priority Data
Feb. 7, 2012 (CN) 201210026313.5

(51) Int. Cl. F28F 3/02; H05K 7/20; F28F 13/12; G06F 1/20

(52) U.S. Cl. 361/679.47; 361/704; 165/80.3

(57) ABSTRACT

A heat dissipating system includes an enclosure body, a plurality of heat generating elements, and a heat dissipating module. The enclosure body includes a mounting panel. The mounting panel defines a mounting opening. The plurality of heat generating elements is mounted to an inner side of the mounting panel and covers the mounting opening. The heat dissipating module includes a base and a plurality of fins extending from the base. The base is mounted to an outer side of the mounting panel to cover the mounting opening and to contact the plurality of heat generating elements.

### BACKGROUND

1. Technical Field

The disclosure generally relates to heat dissipating systems, especially, to a heat dissipating system with a heat dissipating module.

2. Description of Related Art

A conventional motor control box is used for controlling a mechanical arm. The motor control box defines a few openings for airflow to prevent dust or oil from contaminating the box, which may cause heat to not be dissipated efficiently out of the box.

Thus, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a heat dissipating system.

FIG. 2 is an assembled view of FIG. 1.

FIG. 3 is another assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

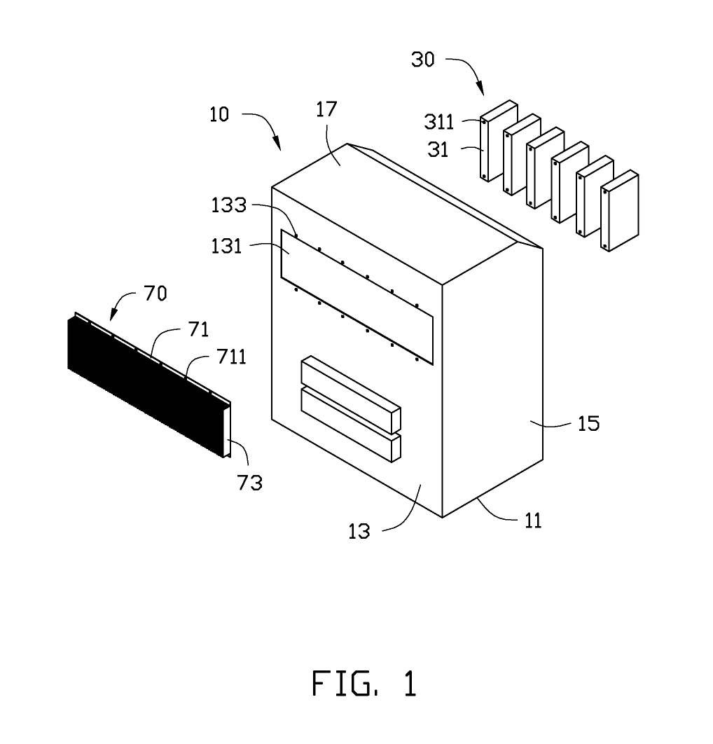

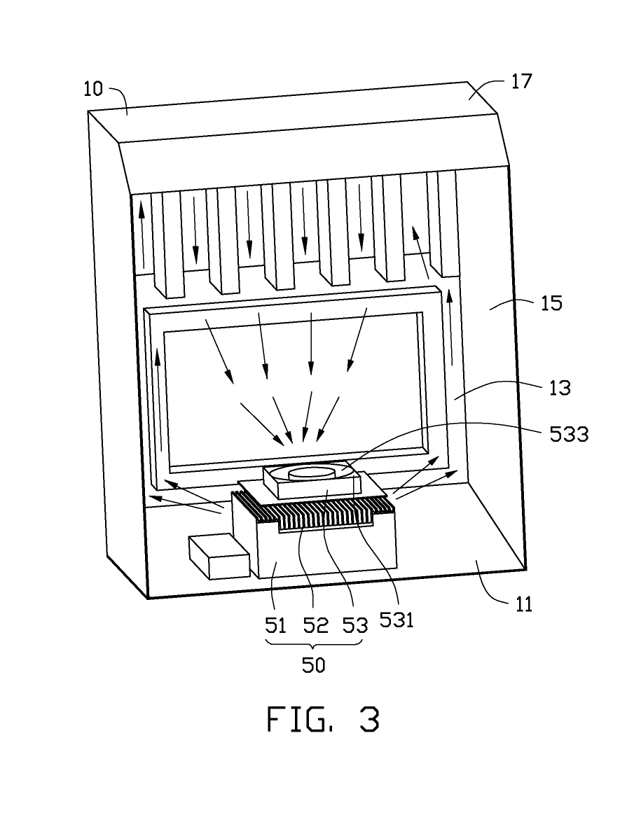

FIG. 1 illustrates one embodiment of a heat dissipating system. The heat dissipating system includes an enclosure body 10, a cover panel (not shown) covering the enclosure body 10, a plurality of heat generating elements 30, a control computer 50 (shown in FIG. 3), and a heat dissipating module 70. In one embodiment, the heat generating elements 30 are motor controllers.

The enclosure body 10 includes a bottom panel 11, a mounting panel 13 extending from the bottom panel 11, two side panels 15 extending from the bottom panel 11, and a top panel 17 extending from the mounting panel 13. The mounting panel 13 is substantially perpendicular to the bottom panel 11, two side panels 15 are substantially parallel to each other and substantially perpendicular to the bottom panel 11. The mounting panel 13 defines a mounting opening 131 and a plurality of mounting holes 133 surrounding to the mounting opening 131.

The heat generating elements 30 are substantially parallel to each other and are substantially perpendicular to the bottom panel 11 and the mounting panel 13. Each heat generating element 30 includes a securing panel 31. The securing panel 31 defines two securing holes 311 corresponding to the mounting holes 133. The securing panel 31 is substantially parallel to the mounting panel 13.

FIG. 3 illustrates the control computer 50 of the embodiment. The computer 50 includes a computer body 51 mounted to the bottom panel 11, a heat sink 52 mounted to the computer body 51, and a fan 53 mounted on the heat sink 52. The fan 53 includes two plane panels 531 substantially parallel to each other. Each plane panel 531 defines an airflow opening 533. The plane panel 531 is substantially parallel to the bottom panel 11.

The heat dissipating module 70 includes a base 71 and a plurality of fins 73 extending from the base 71. The fins 73 are substantially parallel to each other. The fins 73 are substantially perpendicular to the mounting panel 13. The base 71 defines a plurality of through holes 711 corresponding to the mounting holes 133.

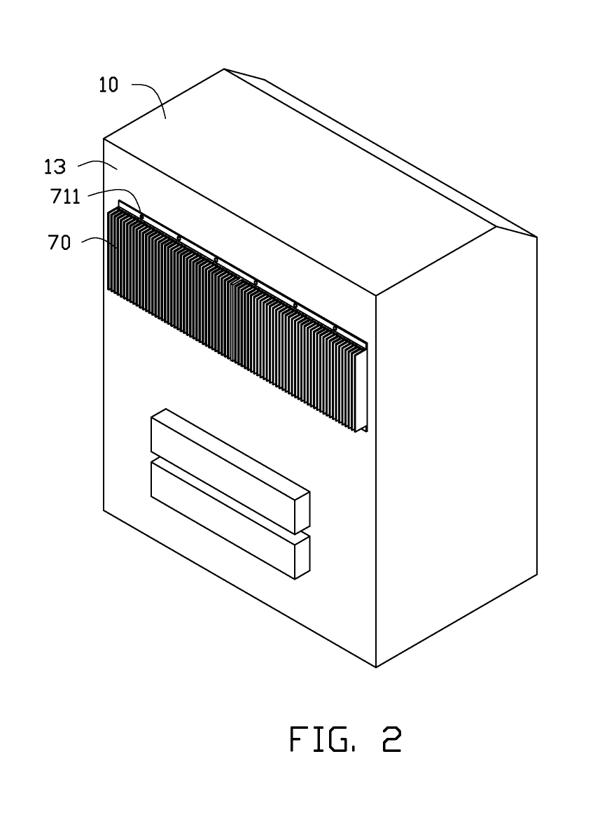

FIGS. 2 and 3 illustrate that in assembly, the heat generating elements 30 are placed on the inner side of the mounting panel 13, to enable the securing holes 311 of the heat generating elements 30 to be aligned with the mounting holes 133 of the mounting panel 13. The heat dissipating module 70 are placed on the outer side of the mounting panel 13 to enable the through holes 711 of the heat dissipating module 70, to be aligned with the mounting holes 133 of the mounting panel 13. A plurality of fasteners (not shown), such as screws, are secured in the through holes 711, the mounting holes 133, and the corresponding to the securing holes 311 to secure the heat dissipating module 70, the mounting panel 13, and the heat generating elements 30 together. At this time, the base 71 of the heat dissipating module 70 covers the mounting opening 131 and contacts the heat generating elements 30. Heat generated by the heat generating elements 30 can be delivered to the fins 73 via the base 71. The cover panel is mounted to cover the enclosure body 10 to integrate a closed enclosure.

FIG. 3 illustrates that in use, the fan 53, airflow flows into the fan 53 and flows out to two sides of the heat generating elements 30. Airflow flows into the fan 53 again from the middle of the heat generating elements 30, thereby dissipating heat from the heat generating elements 30.

It is to be understood, however, that even though numerous characteristics and advantages have been set forth in the foregoing description of embodiments, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A heat dissipating system, comprising:
an enclosure body, the enclosure body comprises a mounting panel, the mounting panel defines a mounting opening;
a plurality of heat generating elements, the plurality of heat generating elements are mounted to an inner side of the mounting panel and cover the mounting opening; and
a heat dissipating module, the heat dissipating module comprises a base and a plurality of fins extending from the base, and the base is mounted to an outer side of the mounting panel to cover the mounting opening and to contact the plurality of heat generating elements.

2. The heat dissipating system of claim 1, further comprising a fan mounted in the enclosure body, wherein the fan comprises a plane panel, the plane panel defines an airflow opening; the plane panel is substantially perpendicular to the mounting panel; and
the plurality of heat generating elements are substantially parallel to each other and perpendicular to the plane panel.

3. The heat dissipating system of claim 2, further comprising a control computer, wherein the control computer comprises a computer body for controlling the plurality of the heat generating elements and a heat sink mounted to the computer body, and the fan is mounted on the heat sink.

4. The heat dissipating system of claim 3, wherein the enclosure body further comprises a bottom panel extending from the mounting panel; the mounting panel is substantially perpendicular to the mounting panel; the control computer is mounted to the bottom panel;
and the computer body contacts the bottom panel.

5. The heat dissipating system of claim 4, wherein the plane panel is substantially parallel to the bottom panel.

6. The heat dissipating system of claim 1, wherein the plurality of fins is substantially perpendicular to the mounting panel.

7. The heat dissipating system of claim 1, wherein the base defines a plurality of through holes; the mounting panel defines a plurality of mounting holes corresponding to the plurality of through holes; and each of the plurality of heat generating elements defines a securing hole corresponding to one of the plurality of mounting holes.

8. The heat dissipating system of claim 7, wherein each of the plurality of heat generating elements comprises a securing panel that is substantially parallel to the mounting panel; the securing hole is defined in the securing panel; and the securing panel contacts the base.

9. The heat dissipating system of claim 1, wherein the plurality of heat generating elements is a plurality of motor controllers.

10. A heat dissipating system, comprising:
an enclosure body, the enclosure body comprises a mounting panel;
a plurality of heat generating elements, the plurality of heat generating elements are mounted to an inner side of the mounting panel; the plurality of heat generating elements are substantially parallel to each other and substantially perpendicular to the mounting panel; and
a fan mounted in the enclosure body, wherein the fan comprises a plane panel, the plane panel defines an airflow opening; the plane panel faces the plurality of heat generating elements; and the plane panel is substantially perpendicular to the mounting panel.

11. The heat dissipating system of claim 10, wherein the plane panel is substantially perpendicular to the plurality of the heat generating elements.

12. The heat dissipating system of claim 10, further comprising a heat dissipating module, wherein the mounting panel defines a mounting opening; the plurality of heat generating elements covers the mounting opening; the heat dissipating module comprises a base and a plurality of fins extending from the base; and the base are mounted to an outer side of the mounting panel to cover the mounting opening and to contact the plurality of heat generating elements.

13. The heat dissipating system of claim 12, wherein the plurality of fins is substantially perpendicular to the mounting panel.

14. The heat dissipating system of claim 12, wherein the base defines a plurality of through holes; the mounting panel defines a plurality of mounting holes corresponding to the plurality of through holes; and each of the plurality of heat generating elements defines a securing hole corresponding to one of the plurality of mounting holes.

15. The heat dissipating system of claim 14, wherein each of the plurality of heat generating elements comprises a securing panel that is substantially parallel to the mounting panel; the securing hole is defined in the securing panel; and the securing panel contacts the base.

16. The heat dissipating system of claim 10, further comprising a control computer, wherein the control computer comprises a computer body for controlling the plurality of the heat generating elements and a heat sink mounted to the computer body, and the fan is mounted on the heat sink.

17. The heat dissipating system of claim 16, wherein the enclosure body further comprises a bottom panel extending from the mounting panel; the mounting panel is substantially perpendicular to the mounting panel; the control computer is mounted to the bottom panel; and the computer body contacts the bottom panel.

18. The heat dissipating system of claim 17, wherein the plane panel is substantially parallel to the bottom panel.

19. The heat dissipating system of claim 10, wherein the plurality of heat generating elements is a plurality of motor controllers.
